(19) United States
(12) Patent Application Publication
(10) Pub. No.: US 2015/0206798 A1
(43) Pub. Date: Jul. 23, 2015

(54) Interconnect Structure And Method of Forming

(71) Applicant: TAIWAN SEMICONDUCTOR MANUFACTURING COMPANY, LTD., Hsin-Chu (TW)

(72) Inventors: Chih-Chien Chi, Hsin-Chu (TW); Huang-Yi Huang, Hsin-Chu (TW); Szu-Ping Tung, Taipei City (TW); Ching-Hua Hsieh, Hsin-Chu (TW)

(21) Appl. No.: 14/158,483

(22) Filed: Jan. 17, 2014

(51) Int. Cl. H01L 21/768; H01L 21/321; H01L 23/532; H01L 21/324

(52) U.S. Cl. CPC H01L 21/76883; H01L 21/324; H01L 21/76834; H01L 21/76802; H01L 21/32115; H01L 23/53238

(57) ABSTRACT

An interconnect structure of an integrated circuit and a method for forming the same are provided. The interconnect structure includes a conductive line, and optionally, a cap layer over the conductive line. A treatment is performed to remove impurities prior to forming a layer, e.g., an etch stop layer, ILD, or the like, over the conductive line and/or the cap layer.

### BACKGROUND

A conventional integrated circuit contains interconnect lines electrically coupled to semiconductor devices and other electrical devices to form an electrical circuit. The interconnect lines generally include layers of conductive lines separated by layers of dielectric material. The conductive lines may include metal patterns of vertically spaced metallization layers electrically interconnected by vias. Metal lines formed in trench-like openings typically extend substantially parallel to the semiconductor substrate. Semiconductor devices of such type, according to current technology, may comprise eight or more levels of metallization to satisfy device geometry and micro-miniaturization requirements.

A common method for forming metal lines or plugs is known as “damascene.” Generally, this process involves forming an opening in the dielectric interlayer, which separates the vertically spaced metallization layers. The opening is typically formed using conventional lithographic and etching techniques. After an opening is formed, the opening is filled with copper or copper alloys to form a via. Excess metal material on the surface of the dielectric interlayer is then removed by chemical mechanical planarization (CMP).

### BRIEF DESCRIPTION OF THE DRAWINGS

For a more complete understanding of the present invention, and the advantages thereof, reference is now made to the following descriptions taken in conjunction with the accompanying drawings, in which:

FIG. 1-3 are cross-sectional views of intermediate stages in the manufacture of an interconnect structure;

FIG. 4-5 are cross-sectional views of intermediate stages in the manufacture of an interconnect structure; and

FIG. 6 is a flowchart illustrating a method of forming an interconnect structure.

### DETAILED DESCRIPTION OF ILLUSTRATIVE EMBODIMENTS

It is understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

As discussed below, treatments are disclosed during the forming of conductive structures, such as interconnect structures, to remove impurities. The removal of impurities reduces or prevents issues related to outgassing, bubbling, peeling, and/or delamination, thereby increasing reliability of the device. While the embodiments are discussed with reference to an interconnect structure, other embodiments may be utilized in other contexts. For example, embodiments such as those disclosed herein may be beneficial to any situation in which a dielectric is formed over a metal conductor.

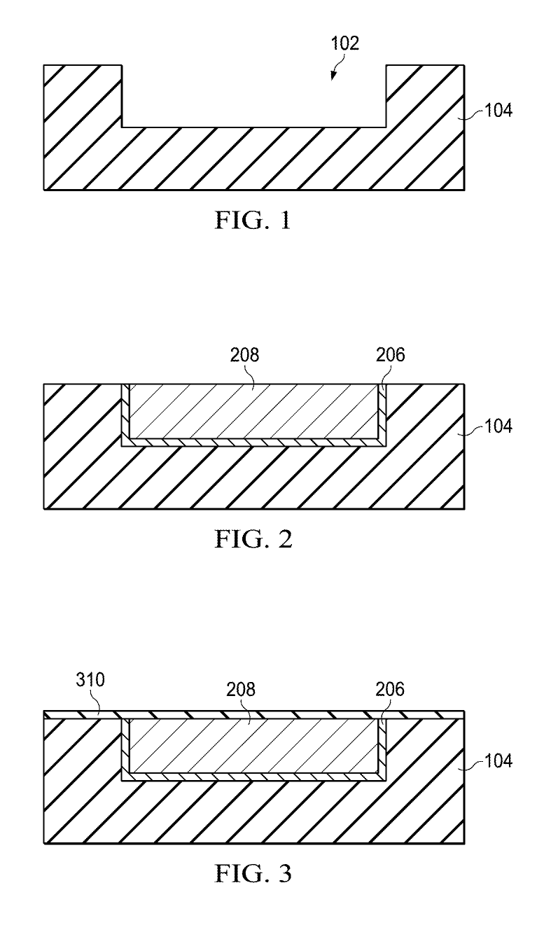

FIGS. 1-3 are cross-sectional views of intermediate stages in the fabrication of an embodiment. Referring first to FIG. 1, there is shown a trench 102 formed in a dielectric layer 104. In an embodiment, the first dielectric layer 104 is an inter-layer dielectric (ILD) and/or an inter-metal dielectric (IMD), and may be, for example, a low dielectric constant value (low-k dielectric) dielectric material having a dielectric constant lower than about 3.5. The dielectric layer 104 may comprise dielectric materials such as oxides, nitrides, carbon-containing dielectric materials, combinations thereof, or the like.

The trench 102 may be formed using, for example, photolithography techniques. Generally, photolithography techniques involve depositing a photoresist material (not shown), which is subsequently irradiated (exposed) and developed to remove a portion of the photoresist material corresponding to the trench 102. The remaining photoresist material protects the underlying material from subsequent processing steps, such as etching. Other layers may be used in the patterning process to form the trench 102. For example, one or more optional hard mask layers may be used. Generally, one or more hard mask layers may be useful in embodiments in which the etching process requires masking in addition to the masking provided by the photoresist material. During the subsequent etching process to form the trench 102, the patterned photoresist material will also be etched, although the etch rate of the photoresist material may not be as high as the etch rate of the trench 102. If the etch process is such that the patterned photoresist material would be consumed before the etching process is completed, then an additional hard mask may be utilized. The material of the hard mask layer or layers is selected such that the hard mask layer(s) exhibit a lower etch rate than the underlying materials, such as the materials of the first dielectric layer 104.

The first dielectric layer 104 may be etched using any suitable etching process, such as a dry etch, an anisotropic wet etch, or any other suitable anisotropic etch or patterning process. The type of etchant is dependent upon the type of material used to form the first dielectric layer 104.

FIG. 2 illustrates an optional liner 206, such as a diffusion barrier layer, an adhesion layer, or the like, and a conductive line 208 formed in the trench 102. The liner 206 preferably includes titanium, titanium nitride, tantalum, tantalum nitride, or other alternatives. The material of conductive line 208 is a conductive material such as copper, a copper alloy, silver, gold, tungsten, aluminum, or the like. In an embodiment, the conductive line 208 is a copper line formed by depositing a thin seed layer of copper or copper alloy and filling the trench 102 by, for example, electro-plating, electro-less plating, deposition, or the like. A chemical mechanical planarization (CMP) may be performed to level the surface of conductive line 208 and/or the optional liner 206, and to remove excess material from a surface of the first dielectric layer 104.

Impurities resulting from, for example, the CMP process may result in peeling or bubble formation in an overlying layer. Additionally, peeling or bubble formation may result from out gassing of the conductive material. As discussed in greater detail below, a treatment is performed to remove impurities from the surface and reduce out gassing, thereby preventing or reducing peeling and bubble formation.

In an embodiment, the treatment comprises a thermal process, with a gas soak or without gas (e.g., in a vacuum). For example, a thermal process can be performed at a temperature of about 25° C. to about 500° C. under pressure from vacuum (pressure <100 mTorr) to 50 Torr for a time period of 5 sec to about 30 min in an ambient of vacuum, inert gas (e.g., Ar, He, etc.) or reduction gas (e.g., H₂, NH₃, etc.). As one example, the wafer is placed on a heated surface at about 400° C. for about 5 minutes in a vacuum of 10⁻⁶ mTorr.

In another embodiment, the treatment is a plasma process, such as a direct or remote plasma process using Ar, H₂, NH₃, combinations thereof, or the like at a flow rate of about 1 sccm to about 10,000 sccm at a pressure of about 1 mTorr to about 100 Torr and at power of about 1 Watts to about 2000 Watts and at a temperature of about 25° C. to about 400° C. As one example, the plasma process may use H₂ process gas at a power of 400 Watts using a pressure of 100 mTorr and a temperature of 300° C.

FIG. 3 illustrates a second dielectric layer 310 formed over the first dielectric layer 104 in accordance with an embodiment. The second dielectric layer 310 may include one or more dielectric layers. For example, FIG. 3 illustrates an embodiment in which the second dielectric layer 310 is an etch stop layer (ESL) or any other applicable layer. As another example, the second dielectric layer 310 may be an ILD/IMD layer.

In an embodiment, the second dielectric layer 310 is conformally deposited using, for example, CVD, ALD, PVD, the like, or a combination thereof. In embodiments in which the second dielectric layer is an etch stop layer, the material of the second dielectric layer 310 is selected such that an etch rate of the material of the second dielectric layer 310 is relatively small as compared to an etch rate of an overlying dielectric layer, such as an IMD/ILD layer, thereby effectively stopping (or slowing) the etch process. The second dielectric layer may be formed of SiN, SiC, SiCO, SiCN, SION, or the like. In embodiments, the second dielectric layer is a low-k dielectric material having a dielectric constant less than 3.5.

As noted above, by treating the first dielectric layer 104 and the conductive line 208 to remove impurities prior to forming the second dielectric layer 310, less peeling and outgassing is observed, thereby increasing the reliability and yield.

Thereafter, further processing may be performed. For example, additional dielectric layers and metallization layers may be formed to interconnect various elements, contact pads and passivation layers may be formed, and the like.

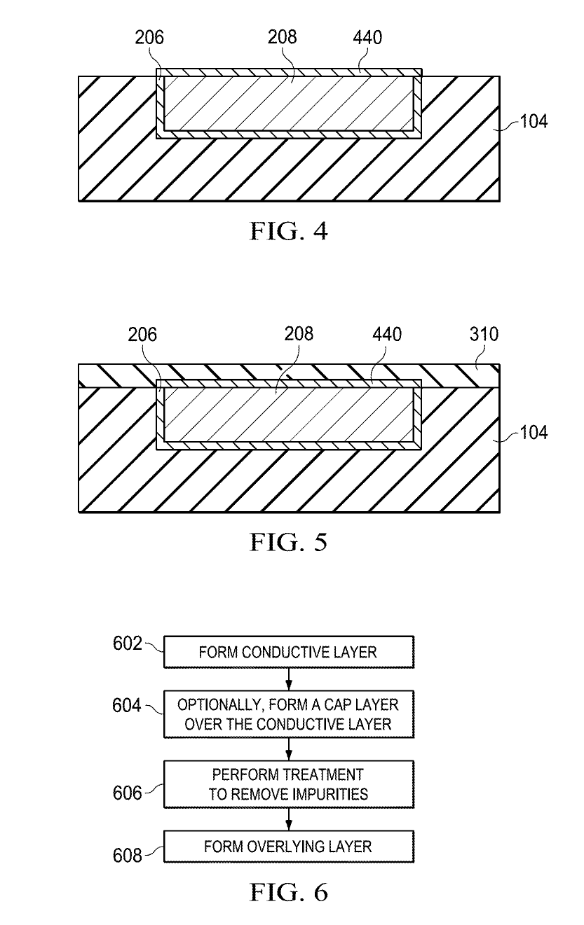

FIGS. 4 and 5 are cross-sectional views of intermediate stages in the fabrication of another embodiment. The process illustrated in FIGS. 4 and 5 assume processes performed with reference to FIGS. 1 and 2 have already been performed, wherein like reference numerals refer to like elements. Accordingly, FIG. 4 illustrates the structure of FIG. 2 after forming a cap layer 440 in accordance with an embodiment.

In an embodiment, the cap layer 440 comprises materials such as copper, cobalt, nickel, tungsten, molybdenum, tantalum, boron, iron, phosphorus, and combinations thereof. These materials may exist in the form of CoP, CoB, CoWP, CoWB, NiWP, CoSnP, NiWB, NiMoP, and combinations thereof. In an embodiment, the cap layer 440 has a thickness of about 25 Å to about 200 Å, although it may have a greater or smaller thickness. The cap layer 440 may be a single layer or a composite layer comprising more than one sub layer. Similarly, each of the sub layers may comprise cobalt, nickel, tungsten, molybdenum, tantalum, boron, iron, and phosphorus. These materials may exist in each sub layer in the form of CoP, CoB, CoWP, CoWB, NiWP, CoSnP, NiWB, NiMoP, and combinations thereof. Other materials are within the contemplated scope of the invention, as well.

In an embodiment, the cap layer 440 is selectively formed by electroless plating, CVD, and ALD. As the conductive line 208 is conductive and first dielectric layer 104 is not conductive, the cap layer 440 may be selectively formed on the conductive line 208 and top edges of the liner 206, if conductive. In other embodiments, the cap layer 440 is blanket deposited using commonly used techniques such as sputtering, PVD, and the like. The portion of the cap layer 440 located on the top surface of the first dielectric layer 104 is then etched.

Thereafter, a treatment is performed to remove impurities from a surface of the cap layer 440 and a surface of the first dielectric layer 104 prior to forming an overlying layer. The impurities may result from, for example, the CMP process may result in peeling or bubble formation in an overlying layer. Additionally, peeling or bubble formation may result from out gassing of the conductive material. As discussed in greater detail below, a treatment is performed to remove impurities from the surface and reduce out gassing, thereby preventing or reducing peeling and bubble formation.

Similar treatments such as those discussed above with reference to FIG. 2 may be used in this embodiment. For example, the treatment may include a thermal process, a plasma treatment, a gas soak, or the like, using process conditions such as those discussed above.

FIG. 5 illustrates the second dielectric layer 310 formed over the first dielectric layer 104 in accordance with an embodiment. As discussed above, the treatment removes impurities that may cause delamination or bubbling issues between the cap layer 440 and the second dielectric layer 310. The second dielectric material may be formed of similar materials using similar processes as those discussed above.

Thereafter, further processing may be performed. For example, additional dielectric layers and metallization layers may be formed to interconnect various elements, contact pads and passivation layers may be formed, and the like.

Referring now to FIG. 6, a method of forming an interconnect structure is provided in accordance with an embodiment. The method begins in step 602, wherein a conductive layer is formed. For example, the conductive layer may be a conductive line formed in a dielectric layer as described above with reference to FIGS. 1 and 2. Next and optionally in step 604, a cap layer may be formed over the conductive layer such as that discussed above with reference to FIG. 4. In step 606, a treatment is performed to remove impurities from, for example, a CMP process, capping process, or the like. An overlying layer, such as an etch stop layer, ILD, or the like, is formed in step 608. As a result of the treatment process, issues related to bubbling, peeling, delamination, outgassing, and the like are reduced and/or prevented.

In an embodiment, a method for forming an interconnect structure is provided. The method includes providing a workpiece, wherein the workpiece has a first dielectric layer and a conductive feature formed in the first dielectric layer. The workpiece is treated to remove impurities. After treating the workpiece, a second dielectric layer is formed over the conductive feature.

In another embodiment, another method of forming an interconnect structure is provided. The method includes forming a trench in a first dielectric layer and filling the trench with a conductive material. The conductive material is planarized with an upper surface of the first dielectric layer. Impurities are removed and a second dielectric layer is formed over the first dielectric layer and the conductive material.

In yet another embodiment, another method of forming an interconnect structure is provided. The method includes providing a workpiece having a copper line in a first dielectric layer. The workpiece is treated to remove impurities and an overlying layer is formed over the first dielectric layer.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming an interconnect structure, the method comprising:
providing a workpiece, the workpiece having a first dielectric layer and a conductive feature formed in the first dielectric layer;
treating the workpiece to remove impurities; and
after the treating, forming a second dielectric layer over the conductive feature.

2. The method of claim 1, wherein the treating the workpiece comprises a thermal process.

3. The method of claim 2, wherein the thermal process comprises vacuum process.

4. The method of claim 2, wherein the thermal process comprises a gas soak process in Ar, H₂, NH₃, or a combination thereof.

5. The method of claim 1, wherein the treating the workpiece comprises a plasma process.

6. The method of claim 5, wherein the plasma process uses an Ar plasma, an H₂ plasma, an NH₃ plasma, or a combination thereof.

7. The method of claim 5, wherein the plasma process is a remote plasma process.

8. The method of claim 5, wherein the plasma process is a direct plasma process.

9. The method of claim 1, further comprising forming a cap layer over the conductive feature prior to the treating.

10. A method for forming an interconnect structure, the method comprising:
forming a trench in a first dielectric layer;
filling the trench with a conductive material;
planarizing a surface of the conductive material;
removing impurities; and
forming a second dielectric layer over the first dielectric layer and the conductive material.

11. The method of claim 10, wherein the removing comprises a thermal process.

12. The method of claim 11, wherein the thermal process comprises vacuum process or gas soak process in Ar, H₂, NH₃, or a combination thereof.

13. The method of claim 10, wherein the removing comprises a plasma process.

14. The method of claim 13, wherein the plasma process uses an Ar plasma, an H₂ plasma, an NH₃ plasma, or a combination thereof.

15. The method of claim 13, wherein the plasma process is a remote plasma process.

16. The method of claim 13, wherein the plasma process is a direct plasma process.

17. The method of claim 10, further comprising forming a cap layer over the conductive material prior to the removing.

18. A method for forming an interconnect structure, the method comprising:
providing a workpiece having a copper line in a first dielectric layer;
forming a cap layer over the copper line;
removing impurities from the workpiece; and
forming an overlying layer over the first dielectric layer.

19. The method of claim 18, wherein the removing comprises a thermal process, a gas soak, or a plasma process.

20. The method of claim 18, wherein the removing uses Ar, H₂, or NH₃.
